(19) United States
(12) Patent Application Publication
(10) Pub. No.: US 2026/0074545 A1
(43) Pub. Date: Mar. 12, 2026

(54) ELECTRONIC SYSTEM FOR TESTING PERFORMANCES OF DEVICE UNDER LOW POWER ENVIRONMENT AND METHOD OF OPERATING THE SAME

(71) Applicant: SK hynix Inc., Gyeonggi-do (KR)

(72) Inventors: Min Young EOM, Gyeonggi-do (KR); Byung Kook MOON, Gyeonggi-do (KR)

(21) Appl. No.: 19/017,791

(22) Filed: Jan. 13, 2025

(30) Foreign Application Priority Data
Sep. 12, 2024 (KR) 10-2024-0125022

(51) Int. Cl. H02J 7/00; G01R 31/371; G01R 31/385

(52) U.S. Cl. CPC H02J 7/933; G01R 31/371; G01R 31/385; H02J 7/40; H02J 7/82

(57) ABSTRACT

An electronic system may include an electronic device and a power maintenance device. The electronic device may include a battery and a memory. The memory may include a test function block configured to monitor a level of the battery to generate a control signal for maintaining the level of the battery within a range of a set low level. The power maintenance device may control an electrical connection between an external power source and the battery based on the control signal.

### CROSS-REFERENCES TO RELATED APPLICATION

The present application claims priority under 35 U.S.C. § 119(a) to Korean application number 10-2024-0125022, filed on Sep. 12, 2024, which is incorporated herein by reference in its entirety.

### BACKGROUND

### 1. Technical Field

Embodiments of the present disclosure relate to a technology for testing performances of a device, and more specifically to an electronic system for testing the performances of the device and a method of operating the same.

### 2. Related Art

An electronic device, such as, a smartphone, a tablet PC, a portable multimedia player (PMP), a personal digital assistant (PDA), a laptop personal computer (laptop), and a wearable device, such as a wrist watch and a head-mounted display (HMDs) may include a battery to make them portable.

A Lithium-ion (Li-ion) battery, which may be commonly used in the electronic device, may be characterized by a rapid decrease in an output voltage level when discharged below a certain level, especially at a low temperature. In addition, the Li-ion battery may be characterized by a decrease in battery capacity as the number of charge and discharge cycles may increase, resulting in a decrease in an ability to maintain a good battery level (for example, appropriate battery capacity) for a long time and an accelerated entry into the low level.

The electronic device with the battery of these properties may be subject to various malfunctions due to an unexpected battery level drop. Accordingly, during testing of the electronic device to verify factors causing the malfunctions, it is necessary to maintain a range of a set low level of the battery.

### SUMMARY

Embodiments of the present disclosure provide an electronic system for testing the performances of the device and a method of operating the same while maintaining a battery level within a device within a range of a set low level.

According to an embodiment of the present disclosure, there may be provided an electronic system. The electronic system may include an electronic device and a power maintenance device. The electronic device may include a battery and a memory. The memory may include a test function block configured to monitor a level of the battery to generate a control signal for maintaining the level of the battery within a range of a set low level. The power maintenance device may control an electrical connection between an external power source and the battery based on the control signal.

According to an embodiment of the present disclosure, there may be provided a method of operating an electronic system. In the method of operating the electronic system, power is applied to an electronic device including a battery. A power maintenance device is driven by selectively supplying the power based on an external power source to the battery. A test function block included in a memory of the device may be driven. A level of the battery in the device may be maintained within a range of a set low level under control of the test function block. Performances of the device may be tested under control of the test function block.

According to an embodiment of the present disclosure, there may be provided an electronic device. The electronic device may include a battery, a memory including a test function block configured to generate a control signal for maintaining a level of the battery within a range of a set low level, and a power maintenance device configured to selectively supply, based on the control signal, power based on an external power source to the battery.

According to embodiments of the present disclosure, the electronic system can easily verify various malfunctions that may occur when the battery of a device is in a set low level below a reference level of the battery.

Further, the electronic system may improve product reliability by reducing failures caused by the battery with the low level.

### BRIEF DESCRIPTION OF THE DRAWINGS

The above and other embodiments, features and advantages of the subject matter of the present disclosure will be more easily understood from the following detailed description taken in conjunction with the accompanying drawings, in which:

FIG. 1 is a block diagram for illustrating a configuration of an electronic system according to an embodiment of the present disclosure;

FIG. 2 is a block diagram for illustrating a configuration of an electronic system according to an embodiment of the present disclosure;

FIG. 3 is a block diagram for illustrating a configuration of a power management module according to an embodiment of the present disclosure;

FIG. 4 is a block diagram for illustrating a test function block (TFB) according to an embodiment of the present disclosure;

FIG. 5 is a flowchart for illustrating a method of operating an electronic system according to an embodiment of the present disclosure; and

FIG. 6 is a flowchart illustrating a detailed process of maintaining a set low level of a battery of a device according to an embodiment of the present disclosure.

### DETAILED DESCRIPTION

Embodiments of the present disclosure are hereinafter described in detail, with reference to the drawings, to facilitate practice by one of ordinary skill in the art to which this disclosure belongs. However, the embodiments of the present disclosure may be implemented in many different forms and are not limited to the embodiments described herein. In connection with the description of the drawings, the same or similar reference numerals may be used for the same or similar components. Further, in the drawings and associated description, descriptions of well-known features and configurations may be omitted for clarity and brevity.

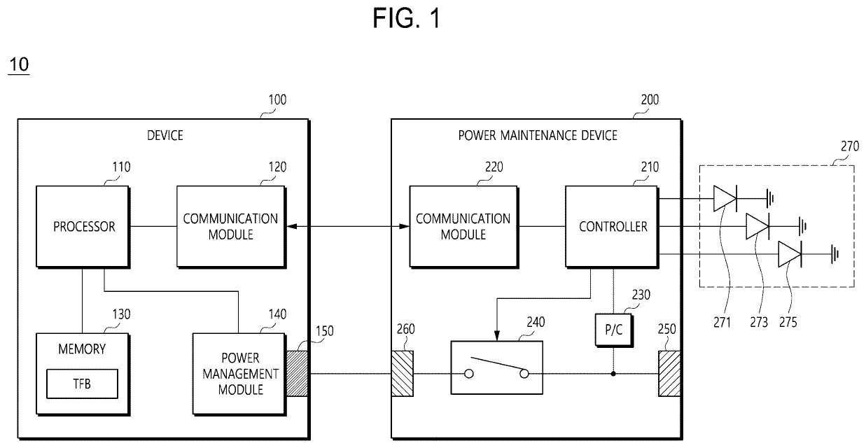

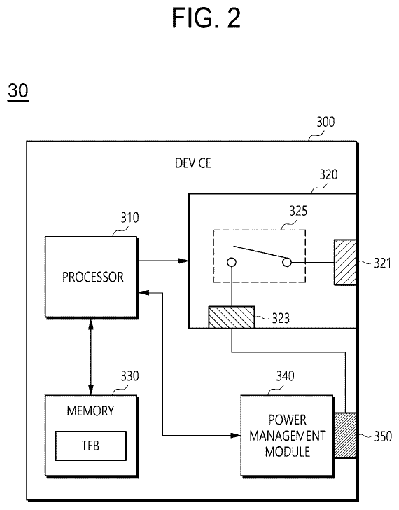

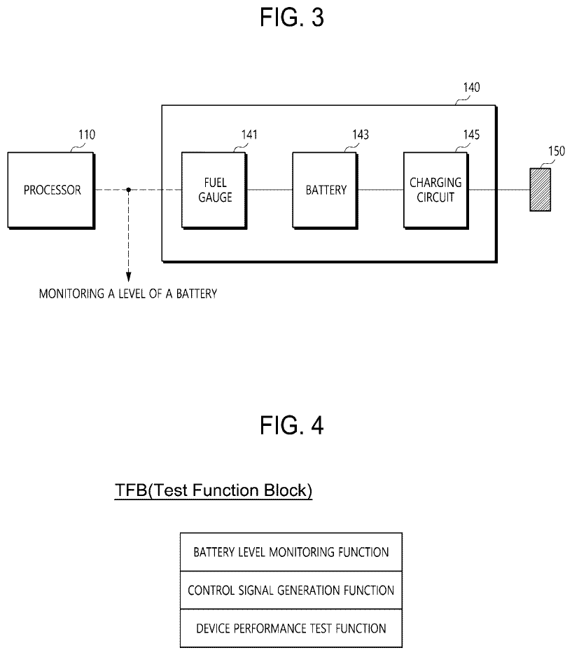

FIG. 1 is a block diagram for illustrating a configuration of an electronic system 10 according to an embodiment of the present disclosure. FIG. 2 is a block diagram for illustrating a configuration of an electronic system 30 according to an embodiment of the present disclosure. FIG. 3 is a block diagram for illustrating a configuration of a power management module 140 according to an embodiment of the present disclosure. FIG. 4 is a block diagram for illustrating a test function block (TFB) according to an embodiment of the present disclosure.

Referring to FIG. 1, the electronic system 10 may include a device (i.e., an electronic device) 100, a test function block TFB included (or stored) in a memory 130 of the device 100, and a power maintenance device 200.

The device 100 may be a portable electronic device operated by power supplied from a battery. For example, the device 100 may include, but is not limited to, a smartphone, tablet PC, a portable multimedia player (PMP), a personal digital assistant (PDA), a laptop personal computer (laptop PC), and a wearable device such as a wrist watch or head-mounted display (HMD), but it will be appreciated that the device 100 may include any electronic device utilizing a battery.

The device 100 may include a processor 110, a communication module 120, a memory 130 and a power management module 140. The device 100 may further include a charging terminal 150 electrically and physically coupled to the power management module 140. Further, although not shown in FIG. 1, the device 100 may further include various other configurations, such as an input module, an acoustic output module, a display module, an audio module, a sensor module, an interface, a haptic module, a camera module, a subscriber identification module, an antenna module, and the like.

The processor 110 may control most of operations of the device 100. For example, the processor 110 may perform a software to control at least one other component of the device 100 (e.g., a hardware or software component) connected to the processor 110. The processor 110 may perform various data processing or computations. For example, the processor 110 may include a main processor (not shown) (e.g., a central processing circuit or processor) or a secondary processor (not shown) that may operate independently of or in conjunction with the main processor (e.g., a graphics processing circuit, a neural processing unit (NPU), an image signal processor, a sensor hub processor, or a communications processor). For example, when the device 100 may include the main processor and the secondary processor, the secondary processor may be configured to use less power than the main processor, or to specialize in a given function. The secondary processor may be implemented independently of, or as part of, the main processor.

The communication module 120 may be configured to communicate with the power maintenance device 200. For example, the communication module 120 may support an establishment of a wired or wireless communication channel between the device 100 and an external electronic device (e.g., the power maintenance device 200, another device, or a server), as well as communication through the established communication channel. In an embodiment, the communication module 120 may include a wireless communication module (e.g., a cellular communication module, a near field communication module, or a global navigation satellite system (GNSS) communication module) or a wired communication module (e.g., a local area network (LAN) communication module, or a power line communication module).

The memory 130 may store various data used by at least one component of the device 100 (e.g., the processor 110). The data may include, for example, input data or output data for software, including an operating system, a middle ware, or an application, and instructions associated therewith. The memory 130 may include a volatile memory or a non-volatile memory. In an embodiment, the memory 130 may include a test function block TFB for testing performances of the device 100. For example, the test function block TFB may be stored in the memory 130 of the device 100.

The power management module 140 may manage the power supplied to the device 100. Referring to FIG. 3, the power management module 140 may include a fuel gauge 141, a battery 143 and a charging circuit 145.

The fuel gauge 141 may detect a voltage level of the battery 143 and provide the detected a voltage level of the battery 143 to the processor 110. In an embodiment, the test function block TFB stored in the memory 130 may monitor the voltage level of the battery 143 as detected by the fuel gauge 141. The terms “voltage level of the battery” and “level of the battery” may have the same meaning and may be used interchangeably.

The battery 143 may provide power to at least one component (hardware or software) of the device 100. For example, the battery 143 may include a non-rechargeable primary cell, a rechargeable secondary cell, or a fuel cell. In an embodiment, the battery 143 may include a Li-ion battery.

The charging circuit 145 may be configured to charge the battery 143 using a power input from an external source via the charging terminal 150. The charging circuit 145 may be a known charging circuit.

The test function block TFB may monitor the level of the battery 143 embedded in the device 100. The test function block TFB may generate a control signal to maintain the level of the battery 143 within a range of a set low level. The test function block TFB may provide the control signal to the power maintenance device 200 via the communication module 120.

Further, the test function block TFB may test the performance of the device 100 while maintaining the level of the battery 143 within the range of the set low level. For example, the test function block TFB may control the device 100 to simultaneously perform at least two operations with high power consumption on the device, when the level of the battery is within the range of the set low level.

Referring to FIG. 4, the test function block TFB may include a battery level monitoring function, a control signal generation function and a device performance testing function. In an embodiment, each function of the test function block TFB may be implemented in a programming language.

The test function block TFB may monitor the level of the battery 143 sensed by the fuel gauge 141 based on the battery level monitoring function.

The test function block TFB may determine whether the level of the battery 143 is within the range of the set low level based on the control signal generation function. The test function block TFB may generate and transmit a first control signal and transmit to the power maintenance device 200 when the level of the battery 143 may reach a minimum value of the range of the set low level. The test function block TFB may generate and transmit a second control signal to the power maintenance device 200 when the level of the battery 143 may reach a maximum value of the range of the set low level.

For example, when the range of the set low level may be about 5% to about 6%, when the level of the battery 143 reaches about 5%, the test function block TFB may generate the first control signal for charging the battery 143. The test function block TFB may then transmit the first control signal to the power maintenance device 200 via the communication module 120. Further, when the level of the battery 143 reaches about 6%, the test function block TFB may generate the second control signal for stopping the charging of the battery 143. The test function block TFB may transmit the second control signal to the power maintenance device 200 via the communication module 120. Accordingly, the battery 143 of the device 100 may maintain the range of the set low level.

As described above, the test of the performances of the device 100 may be conducted while maintaining the range of the set low level of the battery 143. In an embodiment, the test function block TFB may simultaneously perform at least two operations with the high power consumption on the device 100 based on the device performance test functions. For example, the at least two operations with the high power consumption may include reading/writing data, maximizing backlight brightness, turning on a Wi-Fi functionality, turning on a Bluetooth functionality, running a gaming application, etc.

Further, the test function block TFB may store a log record related to an error (or malfunction) in the memory 130 when the error (or malfunction) may be generated in the process of testing the performance of the device 100 based on the device performance test function. Accordingly, various errors (or malfunctions) generated in the low level of the battery 141 of the device 100 may be easily verified. A defect rate of a product may be reduced by reflecting the verification results.

The power maintenance device 200 may control an electrical connection between the external power source (not shown) and the battery 143 in response to control signals generated by the test function block TFB. In an embodiment, the power maintenance device 200 may supply the power supplied from the external power source to the charging circuit 145, when the power maintenance device 200 receives the first control signal for charging the battery 143. Further, the power maintenance device 200 may cut off the power supplied from the external power source to the charging circuit 145 when the power maintenance device 200 receives the second control signal for stopping the charging of the battery 143. The first and second control signals may be provided from the test function block TFB.

Referring to FIG. 1, the power maintenance device 200 may include a first connector 250, a second connector 260, a power switch 240, a controller 210, a power converter (P/C) 230, and a communication module 220

The first connector 250 may be electrically connected to the external power source. The second connector 260 may be electrically connected to the charging terminal 150, which may be electrically connected to the charging circuit 145. The power switch 240 may be connected between the first connector 250 and the second connector 260 to turn on or off the power supplied from the external power source to the battery 143. The controller 210 may be configured to control the power switch 240 based on the first and second control signals provided from the test function module TFB. The power converter (P/C) 230 may be configured to convert the power supplied from the external power source to a set level and to supply a converted power to the controller 210. The communication module 220 may be configured to communicate with the device 100.

In addition, the power maintenance device 200 may include a display module 270 configured to display various operational states. In an embodiment, the display module 270 may include a first display device 271, a second display device 273, and a third display device 275 The first display device 271 may be configured to display whether the power maintenance device 200 is powered on. The second display device 273 may be configured to display whether the power maintenance device and the device are in communication. The third display device 275 may be configured to display whether the level of the battery 143 of the device 100 is out of the range of the set low level. For example, the first to third display devices 271, 273 and 275 may include a LED (light emitting diode), but the embodiments are not particularly limited to this.

Although FIG. 1 may illustrate the electronic system 10 having the device 100 and the power maintenance device 200 separately, the embodiments may not be particularly limited to this. For example, as shown in FIG. 2, a power maintenance device 320 may be included as a part of the configuration of a device 300. The power maintenance device 320 may include a first connector 321 electrically connected to an external power source, a second connector 323 electrically connected to a charging terminal 350 electrically connected to the charging circuit 145 (see FIG. 3), and a power switch 325 connected between the first connector 321 and the second connector 323 and configured to supply or cut off power supplied by the external power source to the battery 143 (see FIG. 3). In an embodiment, the power switch 325 of the power maintenance device 320 may be controlled by a processor 310 of the device 300.

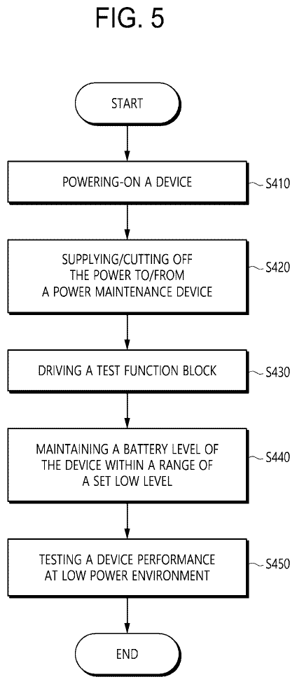

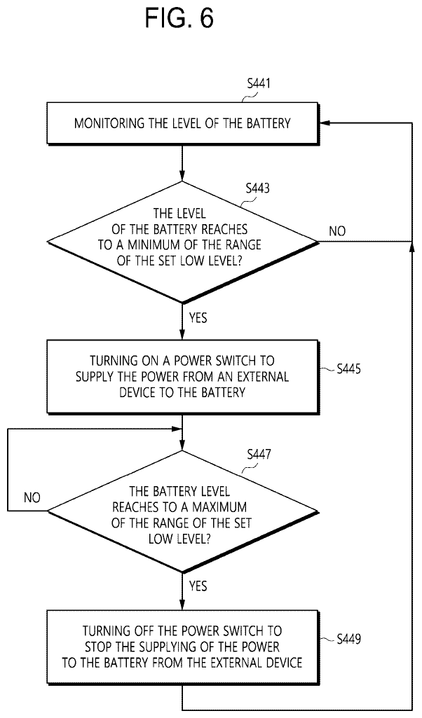

FIG. 5 is a flowchart illustrating a method of operating an electronic system based on an embodiment of the present disclosure. FIG. 6 is a flowchart illustrating a detailed process of maintaining a set low level of a battery of a device according to an embodiment of the present disclosure. In describing the method of operating the electronic system based on embodiments of the present disclosure with reference to FIGS. 5 and 6, reference may be made to at least one of the drawings of FIGS. 1 to 4.

The device 100 including the battery 143 may be powered on (at operation S410).

A power may be supplied to, or cut off from the power maintenance device 200. The power may be provided from an external power source (at operation S420).

The test function block TFB included (for example, stored) in the memory 130 of the device 100 may be driven (at operation S430). For example, the test function block TFB may monitor the level of the battery 143 sensed by the fuel gauge 141 based on the battery level monitoring function.

The level of the battery 143 of the device 100 may be maintained within the range of the set low level, based on the test function block TFB (at operation S440). Referring to FIG. 6, operation S440 may be more specifically described as follows.

The test function block TFB may monitor the level of the battery 143 sensed by the fuel gauge 141 based on the battery level monitoring function (at operation S441).

The test function block TFB may determine whether the level of the battery 143 reaches the minimum value of the range of the set low level, based on the control signal generation function. When, as a result of the determination, the level of the battery 143 reaches the minimum value, the power switch 240 may be turned on, to supply the power from the external device to the battery 143 (at operation S445). And then, when the level of the battery 143 does not reach the minimum value, the test function block TFB monitors the level of the battery 143 again (at operation S441).

The test function block TFB may generate the first control signal for charging the battery 143 based on the control signal generation function (at operation S445). The test function block TFB may transmit the first control signal to the power maintenance device 200. When the power maintenance device 200 receives the first control signal, the controller 210 of the power maintenance device 200 may turn on the power switch 240 so that the power supplied from the external power source may be supplied to the battery 143. Accordingly, the power may be provided to the charting circuit 145 through the power switch 240, which is powered on, the second connector 260, and the charging terminal 150 of the device 100. The charging circuit 145 may charge the battery 143 using the supplied power.

The test function block TFB may determine whether the level of the battery 143 reaches the maximum value of the range of the set low level based on the control signal generation function (at operation S447). For example, the test function block TFB may monitor the level of the battery 143 that has started charging at operation S445 to determine whether the maximum value of the range of the set low level has been reached. When, as a result of the determination, the level of the battery 143 has reached the maximum value, an operation S449 may be performed. Further, when the level of the battery 143 has not reached the maximum value, the operation S447 may be repeatedly performed.

The test function block TFB may generate the second control signal for stopping the charging of the battery 143 based on the control signal generation function, and may transmit the generated second control signal to the power maintenance device 200 (at operation S449). When the power maintenance device 200 receives the second control signal, the controller 210 of the power maintenance device 200 may turn off the power switch 240 so that the power is cut-off from the battery 143. Accordingly, the power input to the first connector 250 from the external power source may be cut-off from being transmitted to the second connector 260.

As such, the test function block TFB may repeatedly perform operations S441 to S447 based on the level of the battery monitoring function and the control signal generation function to ensure that the battery 143 level of the device 100 may remain within the range of the set low level.

Referring again to FIG. 5, the performances of the device 100 may be tested based on the test function block TFB (at operation S450). In an embodiment, as described above, with the battery 143 level of the device 100 maintained within the range of the set low level, the test function block TFB may simultaneously perform at least two operations with high power consumption on the device 100 based on device performance test functions. For example, the at least two operations with high power consumption may include reading/writing data, maximizing backlight brightness, turning on Wi-Fi functionality, turning on Bluetooth functionality, running a gaming application, etc. Additionally, the test function block (TFB) may store log records associated with the errors (or malfunctions) encountered in the process of testing the performance of the device 100 based on the device performance testing functionality in the memory 130.

It should be understood that the embodiments described above are illustrative and not limiting in all respects. Those skilled in the art will recognize that the invention may be practiced in other embodiments without altering its technical ideas or essential features. The scope of the present disclosure is indicated by the following claims rather than by the detailed description above, and all modifications or variations derived from the meaning and scope of the claims and their equivalents are to be construed as being within the scope of the present disclosure. Furthermore, the embodiments may be combined to form additional embodiments.

What is claimed is:

1. An electronic system comprising:
an electronic device including a battery and a memory, the memory including a test function block configured to monitor a level of the battery to generate a control signal for maintaining the level of the battery within a range of a set low level; and
a power maintenance device configured to control an electrical connection between an external power source and the battery based on the control signal.

2. The electronic system of claim 1, wherein the electronic device further includes:
a fuel gauge configured to detect the level of the battery; and
a charging circuit configured to charge the battery using power based on the external power source, the power being supplied from the power maintenance device.

3. The electronic system of claim 2, wherein the test function block comprises:
a first function for monitoring the level of the battery detected by the fuel gauge;
a second function for determining whether the level of the battery is within the range of the set low level; and
a third function for
generating and transmitting a first control signal to the power maintenance device when the level of the battery reaches a minimum value of the range of the set low level, and
generating and transmitting a second control signal to the power maintenance device when the level of the battery reaches a maximum value of the range of the set low level.

4. The electronic system of claim 3, wherein the power maintenance device is configured to:
supply the power based on the external power source to the battery when the power maintenance device receives the first control signal from the test function block; and
cut off the power supplied to the battery when the power maintenance device receives the second control signal from the test function block.

5. The electronic system of claim 1, wherein the test function block comprises:
a function for testing performances of the electronic device by simultaneously performing at least two operations with high power consumption on the electronic device when the level of the battery is within the range of the set low level; and
a function for storing log records in the memory when an error is generated while testing the performances of the electronic device.

6. The electronic system of claim 5, wherein at least two operations with the high power consumption include reading/writing data, maximizing backlight brightness, turning on a WIFI functionality, turning on a Bluetooth functionality and running game applications.

7. The electronic system of claim 1, wherein the electronic device comprises:
a power management module configured to sense the level of the battery and charge the battery using the power based on the external power source; and
a communication module configured to communicate with the power maintenance device.

8. The electronic system of claim 1, wherein the power maintenance device comprises:
a first connector electrically connected to the external power source;
a second connector electrically connected to the battery;
a power switch electrically connected between the first connector and the second connector, and configured to selectively supply the power to the battery;
a controller configured to control the power switch based on the control signal;
a power converter configured to convert the power based on the external power source to a set level of the battery and supply the converted power to the controller; and
a communication module configured to communicate with the electronic device.

9. The electronic system of claim 8, wherein the power maintenance device comprises:
a first display device configured to display whether the power maintenance device is powered on;
a second display device configured to display whether the power maintenance device and the electronic device are in communication; and
a third display device configured to display whether the level of the battery is out of the range of the set low level.

10. The electronic system of claim 9, wherein at least one of the first to third display devices comprises a light emitting diode.

11. A method of operating an electronic system, the method comprising:
applying power to an electronic device including a battery;
driving a power maintenance device by selectively supplying the power based on an external power source to the battery;
driving a test function block stored in a memory included in the electronic device;
maintaining a level of the battery of the electronic device within a range of a set low level under control of the test function block; and
testing performances of the electronic device under control of the test function block.

12. The method of claim 11, wherein maintaining the level of the battery within the range of the set low level comprises:
monitoring the level of the battery;
determining whether the level of the battery reaches a minimum value of the range of the set low level;
supplying the power based on the external power source to the battery when the level of the battery reaches the minimum value of the range of the set low level;
determining whether the level of the battery reaches a maximum value of the range of the set low level; and
cutting off the power based on the external power source from the battery when the range of the set low level of the battery reaches the maximum value of the range of the set low level.

13. The method of claim 12, wherein supplying the battery comprises:
generating a first control signal for charging the battery based on a control signal generation function of the test function block, and transmitting the first control signal to the power maintenance device; and
turning on a power switch to supply the power based on the external power source to the battery when the power maintenance device receives the first control signal.

14. The method of claim 12, wherein cutting off the power comprises:
generating a second control signal for stopping the charging of the battery based on the control signal generation function of the test function block, and transmitting the second control signal to the power maintenance device; and
turning off the power switch to cut-off the power based on the external power source from the battery when the power maintenance device receives the second control signal.

15. The method of claim 11, wherein testing the performances of the electronic device comprises:
simultaneously performing at least two operations with high power consumption on the electronic device based on performance test functions of the test function block; and
storing, based on results obtained by testing the performances of the electronic device, a log record, which relates to errors generated while simultaneously performing the at least two operations.

16. The method of claim 15, wherein at least two operations with high power consumption include reading/writing data, maximizing backlight brightness, turning on a WIFI function, turning on a Bluetooth function and running a game application.

17. An electronic device comprising:
a battery;
a memory including a test function block configured to generate a control signal for maintaining a level of the battery within a range of a set low level; and
a power maintenance device configured to selectively supply, based on the control signal, power based on an external power source to the battery.

18. The electronic device of claim 17, wherein the test function block is configured to simultaneously perform at least two operations with high power consumption on the electronic device while maintaining the level of the battery within the range of the set low level to test performances of the electronic device.
